(19) United States
(12) Patent Application Publication
(10) Pub. No.: US 2009/0212784 A1
(43) Pub. Date: Aug. 27, 2009

(54) Electrical lighting tester for vehicle-towed trailers

(76) Inventors: Joseph E. Kilian, Santa Ana, CA (US); Michael R. Wood, Winchester, CA (US)

Correspondence Address: Morland C. Fischer, Suite 1300, 2030 Main Street, Irvine, CA, 92614, US

(21) Appl. No.: 12/317,198

(22) Filed: Dec. 22, 2008

Related U.S. Application Data
(60) Provisional application No. 61/064,274, filed on Feb. 26, 2008.

(51) Int. Cl. G01R 31/00

(52) U.S. Cl. 324/504

(57) ABSTRACT

A compact, portable electrical tester to test the functionality of the lights of a lighting system of vehicle-towed commercial and utility trailers. By virtue of the presently-disclosed lighting tester, the lights of a trailer can be remotely tested by a single test taker without the presence of a tow vehicle or tow vehicle operator. Housed within the chassis of the lighting tester are a 120-volt AC/12-volt DC power supply and a set of DC test circuits. The DC test circuits are connected between the power supply and different ones of the lights of the trailer to be tested. In the preferred embodiment, each DC test circuit includes a light selection toggle switch that is connected in electrical series with a DC circuit breaker toggle switch. A particular light selection toggle switch is selectively actuated to a closed switch position so that DC power will be supplied from the power supply to illuminate a particular light or group of lights under test. A particular series connected circuit breaker toggle switch is selectively actuated to a closed circuit position to close the DC test circuit in which it is connected. Each of the light selection and circuit breaker toggle switches is accessible to be manually actuated at the front of the chassis.

### CROSS-REFERENCE TO RELATED PATENT APPLICATIONS

This application is related to Provisional Patent Application No. 61/064,274 filed Feb. 26, 2008.

### BACKGROUND OF THE INVENTION

1. Field of the Invention

This invention relates to a compact, portable AC-powered electrical lighting tester having a series of DC test circuits to be used to test the functionality of the lights of vehicle-towed (e.g., commercial and utility) trailers. The testing can be completed with the tow vehicle detached from the trailer and without the test taker having to operate any components (e.g., the brake pedal) located within the vehicle to cause the lights to be illuminated during testing.

2. Background Art

From time-to-time, it is necessary to test the lighting system of a vehicle-towed trailer so that any non-functioning lights can be replaced in order to maintain proper operating conditions when the trailer is in use while attached to the tow vehicle. To accomplish the testing, the tow vehicle is usually connected to the trailer. For example, to test the functionality of the brake lights of the trailer, the brake pedal located within the tow vehicle must first be depressed. Therefore, the overall lighting system of a trailer cannot be reliably tested unless a tow vehicle is on hand and the vehicle is connected to the trailer. In this same regard, the trailer under test must be located at an area that is large enough to accommodate the tow vehicle. The difficulty associated with the conventional testing technique is compounded in cases where the mechanical staff who perform the tests are not also experienced drivers capable of personally backing the tow vehicle into contact with the trailer in tight spaces.

What is even more, a pair of individuals is commonly required to complete the testing. That is, if the brake lights of the trailer are to be tested, a first test taker must be available to depress the brake pedal within the tow vehicle, and a second test taker must be present to visually inspect the illumination of the brake lights at the rear of the trailer.

It may be appreciated from the foregoing that the current method for testing the lights of a trailer is inefficient and relatively costly, because the trailer cannot be tested absent an available tow vehicle and a tow vehicle driver and because at least a pair of test takers are usually required to complete a full battery of tests of the kind required to ensure that all of the lights of the trailer are properly functioning. In the case of a freight company or wherever a large number of trailers will be employed, the inefficiency and cost encountered to test a fleet of trailers is magnified. Therefore, it would be desirable to improve the efficiency and reduce the cost associated with the conventional method for testing the functionality of a trailer lighting system.

### SUMMARY OF THE INVENTION

In general terms, a compact, portable, AC-powered electrical lighting tester is disclosed to be used for testing the functionality of the lighting system of vehicle-towed (e.g., commercial and utility) trailers. By way of example only, the electrical lighting tester of this invention is capable of selectively testing the functionality of some or all of a trailer's brake lights, right and left turn signal indicator lights, running or courtesy lights, and one or more auxiliary lights, such as the tail lights, license plate lights, and the like. By virtue of the lighting tester herein disclosed, the trailer lights can be efficiently and economically tested by a single test taker and without requiring the presence of a tow vehicle connected to the trailer during testing.

The electrical lighting tester includes a chassis within which is located a 120-volt AC/12-volt DC power supply. A power cord is connected through the chassis from an available 120 volt AC wall receptacle to the input of the power supply. The 12 volt DC output of the power supply is supplied to a set of the DC test circuits enclosed by the chassis by means of which a DC voltage is selectively supplied to each of the lights of the trailer to be tested via a plurality of (e.g., seven) conductors surrounded by an output cable that runs through the chassis of the tester. Located at one end of the output cable is a cylindrical female plug that is sized to fit within the a standard electrical male receptacle located near the front of most commercial flatbed semi-trailers, whereby the trailer lights to be tested can be individually powered and illuminated. In cases where the trailer to be tested is a utility trailer for personal use, the cylindrical female plug of the output cable is first coupled to an adapter which is sized and configured to be mated to a male input plug common to most such utility trailers.

A push-button power switch accessible at the face of the chassis is depressed so that the power supply is electrically connected to the AC wall receptacle. Each of the DC test circuits housed within the chassis includes a circuit breaker toggle switch which is manually accessible at the face of the chassis. The circuit breaker toggle switches may all be rotated from an open circuit position to a closed circuit position at the same time or one at a time to complete the corresponding DC test circuits. Each of the DC test circuits includes a light selection toggle switch which is also manually accessible at the face of the chassis and is connected in electrical series with a circuit breaker toggle switch. The light selection toggle switches are rotated one at a time from an open switch position to a closed switch position to connect the DC power supply to a particular one of the trailer lights to be powered for testing via the output cable. A flasher circuit and a pair of LED indicator lights are interconnected with DC test circuits for providing power to and testing the hazard lights and the left and right turn signal indicator lights of the trailer. When the light selection toggle switch for testing either the hazard or turn signal indicator lights is rotated to a closed switch position, the flasher circuit will be energized and the LED indicator lights will flash.

### BRIEF DESCRIPTION OF THE DRAWINGS

FIG. 1 illustrates the chassis for a portable electrical lighting tester according to a preferred embodiment of the present invention having a plurality of manually-accessible switches located at the face thereof to be selectively actuated for energizing respective DC test circuits to provide power to and test the lighting system of a vehicle-towed trailer;

FIG. 2 shows the chassis of the portable electrical lighting tester of FIG. 1 electrically connected between a source of AC voltage and an electrical receptacle of a commercial flatbed semi-trailer;

FIG. 3 shows the chassis of the portable electrical lighting tester of FIG. 1 electrically connected between a source of AC voltage and an electrical plug of a utility trailer by way of a coupler;

FIG. 4 illustrates details of DC test circuits that are housed within the chassis of FIG. 1 by which different ones of the trailer lights of the lighting system can be selectively powered and tested for functionality; and

FIG. 5 is a ladder diagram with details of the coupler shown in FIG. 3 by which the electrical lighting tester is connected to a utility trailer undergoing testing.

### DESCRIPTION OF THE PREFERRED EMBODIMENT

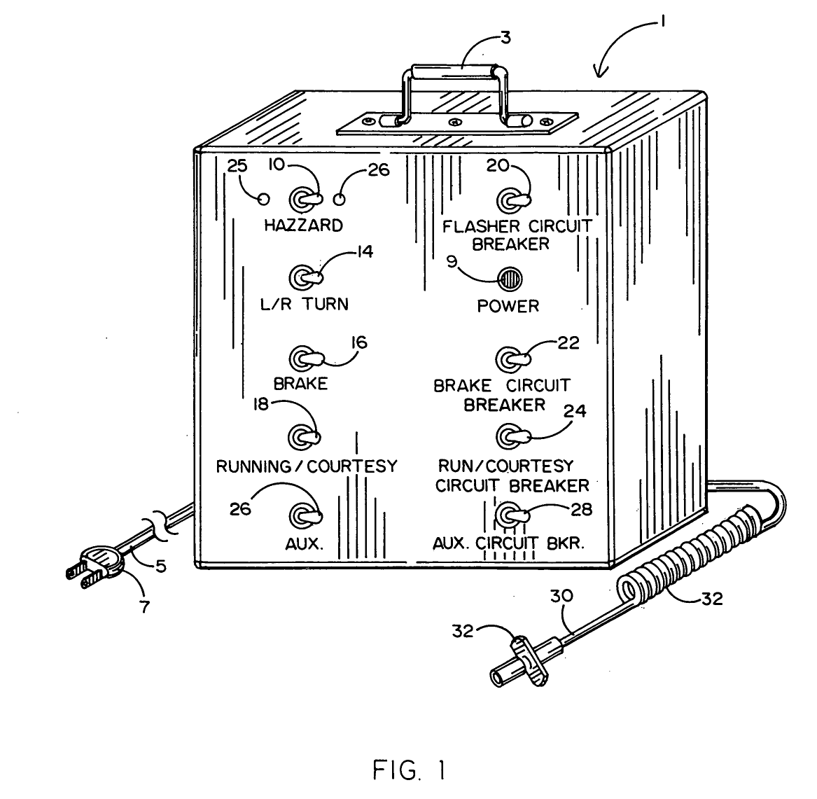

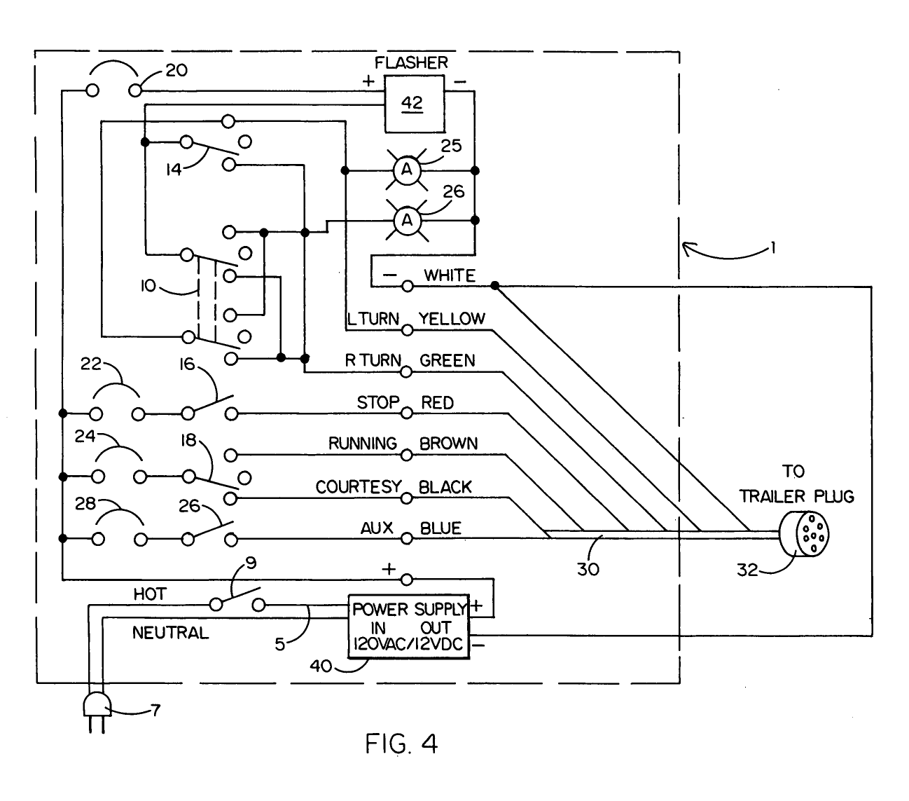

A preferred embodiment of the electrical lighting tester for vehicle-towed trailers which forms the present invention is initially described while referring to FIG. 1 of the drawings where there is shown a compact (e.g., metal) chassis 1 within which a set of DC test circuits (best shown in FIG. 4) for testing the lighting system of a trailer are housed. A handle 3 is secured to the top of the chassis 1 to enable the tester to be transported to the location of the trailer or trailers whose lights are to be tested. A set of manually-operated light selection paddle or toggle switches are accessible at the face of the chassis 1. As will be disclosed in greater detail hereinafter, the light selection toggle switches are selectively actuated (i.e., rotated) when it is desirable to test the functionality of different lights of the trailer to which the tester is electrically interconnected.

Power for the DC test circuits housed within the chassis 1 is provided by way of an input power cord 5 having a two or a three pin plug 7 at one end thereof to be connected to a 120-volt AC electrical receptacle. As best shown in FIG. 4, the opposite end of the input power cord 5 is connected to an internal DC power supply 40 that is housed within the chassis 1. By way of example only, a suitable DC power supply for use herein is the Model No. SS-30 switching power supply manufactured by Astron Corporation of Irvine, Calif. Also located at the face of the chassis 1 is a push-button power switch 9 that is manually operated (i.e., depressed) to connect (or disconnect) the aforementioned DC power supply 40 to the AC voltage receptacle via power cord 5. The internal DC power supply 40 advantageously avoids the requirement for a fully charged 12 volt battery to permit the lighting system of the trailer to be powered for testing.

Details concerning the manually-actuated light selection toggle switches available at the face of chassis 1 and connected in the set of DC test circuits are now explained while continuing to refer to FIG. 1. A light selection toggle switch 10 is selectively actuated to enable the hazard lights of the trailer to be powered and illuminated for testing. Such hazard lights will typically flash to warn approaching motorists of a potentially hazardous condition. Toggle switch 10 is preferably a double-pole, double-throw DC switch having three switch positions. As is illustrated at FIG. 4, the toggle switch 10 remains in a neutral (i.e., center) switch position at those times when the trailer hazard lights are not undergoing testing. When it is desirable to test the left side hazard lights, the toggle switch 10 is rotated to the left switch position. When it is desirable to test the right side hazard lights, the toggle switch 10 is rotated to the right switch position.

A light selection toggle switch 14 at the face of chassis 1 is actuated to enable the left and right turn signal indicator lights of a trailer to be powered and illuminated for testing. Such indicator lights will also flash to warn approaching motorists of an impending turn. Toggle switch 14 is preferably a single-pole, double-throw DC switch having three switch positions. As illustrated at FIG. 4, the toggle switch 14 remains in a neutral (i.e., center) switch position at those times when the turn signal indicator lights are not undergoing testing. When it is desirable to test the left side turn signal lights, the toggle switch 14 is rotated to the left switch position. When it is desirable to test the right side turn signal indicator lights, the toggle switch 14 is rotated to the right switch position.

A light selection toggle switch 16 at the face of chassis 1 is actuated to enable the brake lights of the trailer to be powered and illuminated for testing. Toggle switch 16 is preferably a single-pole, single-throw DC switch having two switch positions. As illustrated at FIG. 4, the toggle switch 16 remains in a neutral (i.e., center) switch position at those times when the brake lights are not undergoing testing. When it is desirable to test the brake lights, the toggle switch 16 is rotated to a single side switch position. In this case, both the right and left side brake lights of the trailer will be tested at the same time.

A light selection toggle switch 18 at the face of chassis 1 is actuated to enable the running or courtesy lights of the trailer to be powered and illuminated for testing. Toggle switch 18 is preferably a single-pole, double-throw DC switch having three switch positions. As illustrated at FIG. 4, the toggle switch 18 remains in a neutral (i.e., center) switch position at those times when the trailer running/courtesy lights are not undergoing testing. When it is desirable to test the left side running/courtesy lights, the toggle switch 18 is rotated to the left switch position. When it is desirable to test the right side running/courtesy lights, the toggle switch 18 is rotated to the right switch position.

A light selection toggle switch 20 at the face of chassis 1 is actuated to enable a flasher circuit (designated 42 in FIG. 4) located within the chassis 1 to be connected between the DC power supply 40 and each of the hazard warning lights selection toggle switch 10 and the left/right turn signal indicator lights selection toggle switch 14. Toggle switch 20 is preferably a single-pole, double-throw DC switch which has two switch positions and functions as a circuit breaker. As illustrated at FIG. 4, the circuit breaker toggle switch 20 will remain in an open circuit (i.e., center) position at those times when the trailer hazard lights and the turn signal indicator lights are not undergoing testing and it is not necessary to connect the aforementioned flasher circuit 42 to either one of the corresponding light selection toggle switches 10 or 14. In this case, the hazard and turn signal indicator lights of the trailer will not receive power from the DC power supply 40. When it is desirable to test either the hazard warning lights or the turn signal indicator lights, the circuit breaker toggle switch 20 is rotated to a closed circuit position, whereby the flasher circuit 42 will be connected to receive power from the DC power supply 40. In this case, the hazard warning or turn signal indicator lights of the trailer will receive DC power so that the operating condition thereof can be verified depending upon the switch positions of the light selection toggle switches 10 and 14.

In this same regard, a pair of indicator lights 25 and 26 are visible at the face of chassis 1. Indicator lights 25 and 26 are preferably DC powered light emitting diodes (LEDs). As illustrated at FIG. 4, the LED indicator lights 25 and 26 are connected in electrical parallel between the flasher circuit 42 and each of the hazard warning lights selection toggle switch 10 and the left/right turn signal indicator lights selection toggle switch 14. When the flasher circuit breaker toggle switch 20 is in the closed circuit position, the flasher circuit 42 will be powered by the DC voltage supply 40 to cause the LED indicator lights 25 and 26 to flash depending upon the switch positions of toggle switches 10 and 14 and the functionality of the hazard warning lights or the turn signal indicator lights of the trailer being tested.

A toggle switch 22 at the face of chassis 1 is actuated to enable the brake lights of the trailer being tested to receive DC power so that the functionality of the brake lights can be verified. Toggle switch 22 is preferably a single-pole, double throw DC switch having two switch positions so as to function as a circuit breaker. As illustrated at FIG. 4, the circuit breaker toggle switch 22 is connected in a DC test circuit between the DC power supply 40 and the brake lights toggle switch 16. Toggle switch 22 can remain in an open circuit (i.e., center) position to open the DC test circuit at those times when the brake lights of the trailer are not undergoing testing and it is not necessary for the brake lights to receive DC power. When it is desirable to test the brake lights, the circuit breaker toggle switch 22 is rotated to a closed circuit position. In this case, the DC test circuit is completed and the brake lights of the trailer will be connected to receive power from the DC power supply 40 depending upon the switch position of the light selection toggle switch 16.

A toggle switch 24 at the face of chassis is actuated to enable the running or courtesy lights of the trailer being tested to receive DC power so that the functionality of the running/courtesy lights can be verified. Toggle switch 24 is preferably a single-pole, double throw DC switch having two switch positions so as to function as a circuit breaker. As illustrated at FIG. 4, the circuit breaker toggle switch 24 is connected in a DC test circuit between the DC power supply 40 and the running/courtesy lights selection toggle switch 18. Toggle switch 24 can remain in an open circuit (i.e., center) position to open the DC test circuit at those times when the running and courtesy lights are not undergoing testing and it is not necessary for these lights to receive DC power. When it is desirable to test the running and courtesy lights, the circuit breaker toggle switch 24 is rotated to a closed circuit position. In this case, the DC test circuit is completed and the running and courtesy lights of the trailer will be connected to receive power from the DC power supply 40 depending upon the switch position of the light selection toggle switch 18.

The face of the chassis 1 also includes one or more optional manually-operated toggle switches 26 and 28. Each of the toggle switches 26 and 28 is preferably a single-pole, double-throw DC switch having a pair of switch positions. The toggle switch 26 is actuated (i.e., rotated) to enable any auxiliary lights found in certain trailers to be powered and tested. As is illustrated at FIG. 4, toggle switch 28 is connected in a DC test circuit between the auxiliary lights toggle switch 26 and the DC power supply 40 so as to function as a circuit breaker. When the auxiliary lights are not being tested, toggle switch 28 can remain in an open circuit (i.e., center) position to open the DC test circuit. When it is desirable to test the auxiliary lights, the auxiliary circuit breaker toggle switch 28 is rotated to a closed circuit position. In this case, the DC test circuit is completed and the auxiliary lights of the trailer will be connected to receive power from the DC power supply 40 depending upon the switch position of the light selection toggle switch 26.

To enable the lights of a trailer to be powered for testing, an output cable 30 extends through the chassis 1 to a connector 32. As will be explained while referring to FIG. 4, the output cable 30 is a patch cable common to the semi-tractor industry which, in the present example, carries seven wires from the set of DC test circuits (of FIG. 4) housed by the chassis 1. In this case, the connector 32 is preferably a seven-pin round notched cylindrical female plug that is adapted to be coupled to an existing male plug of the kind commonly available at the front of most trailers to receive an electrical input. The output cable 30 may have a normally-coiled section 34 which is adapted to expand when it is desirable to couple the female plug 32 to the male plug of the trailer being tested without having to relocate the chassis 1.

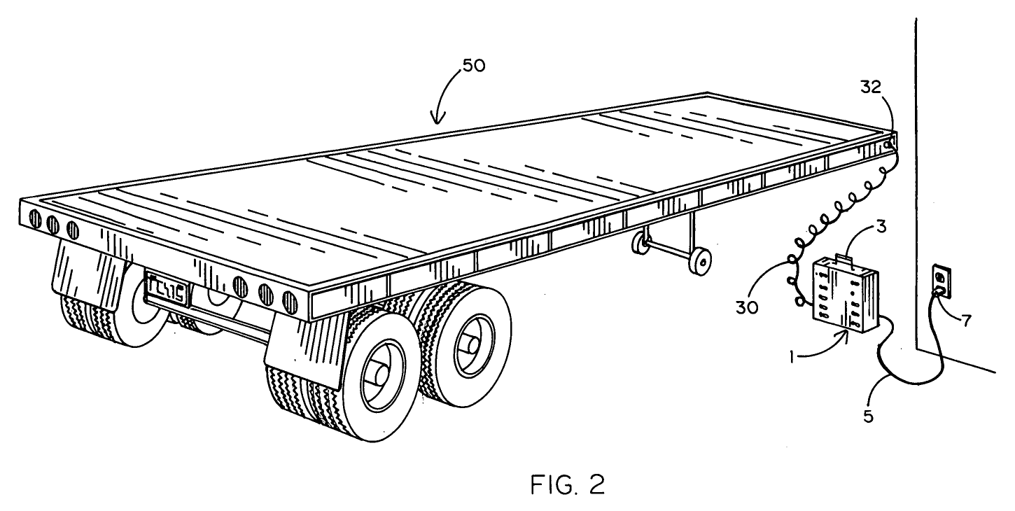

In this regard, FIG. 2 of the drawings illustrates one example of a conventional commercial (e.g., flatbed semi-tractor) trailer 50 to which the presently-disclosed electrical lighting tester is applicable. The tester chassis 1 is conveniently carried at handle 3 to the site of the trailer 50, and the plug 7 at one end of power cord 5 is connected to an available 120-volt AC wall receptacle. The female plug 32 at one end of output cable 30 is coupled to the existing electrical male plug of the trailer 50. Different ones of the electrical lights of the trailer lighting system may now be easily and selectively powered and tested depending upon which of the toggle switches (of FIG. 1) accessible at the face of chassis 1 are actuated.

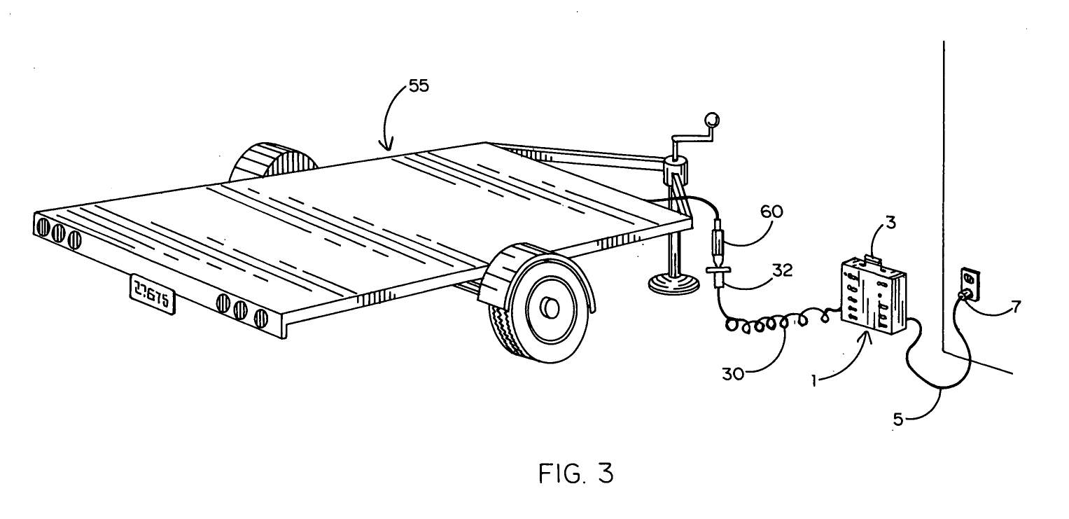

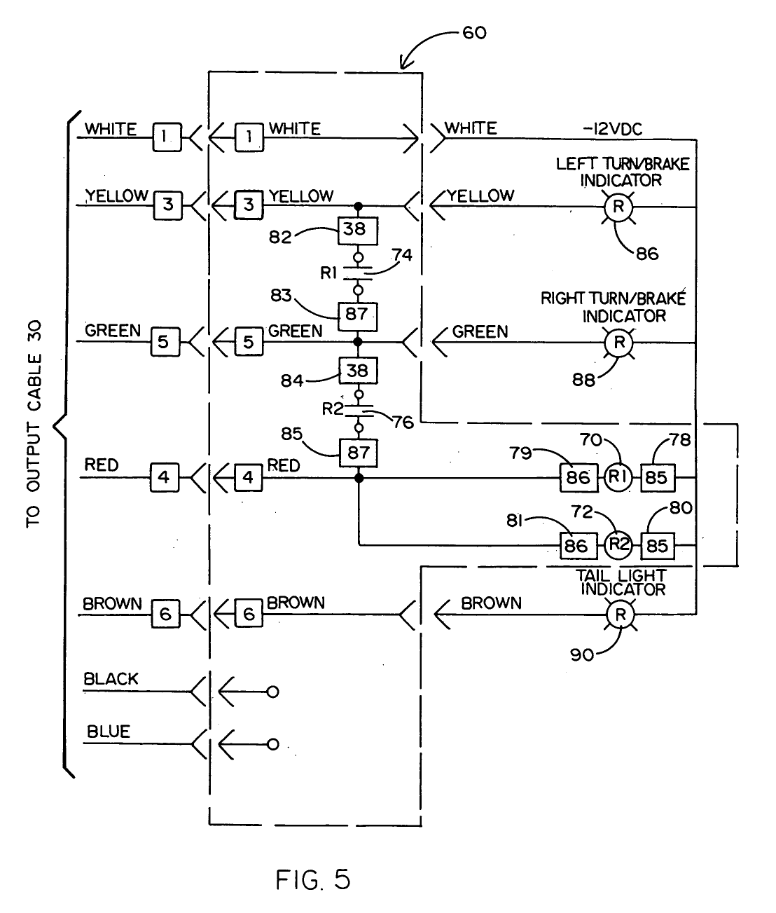

In some cases, the trailer to be tested may be a personal utility trailer of the kind commonly pulled behind a pick-up truck, SVU or van. Such a personal (flatbed) utility trailer 55 is illustrated at FIG. 3 of the drawings. As in the case of the commercial trailer 50 shown at FIG. 2, the chassis 1 of the lighting tester is carried at the handle 3 thereof to the site of the trailer 55 where a plug 7 of power cable 5 is connected to an available AC wall receptacle. The female plug 32 of output cable 30 is connected to an adapter 60 which has particular application for coupling the seven conductors carried by the output cable 30 from the electrical lighting tester to the existing electrical input (e.g., a 4-way flat) plug common to many utility trailers such as that shown in FIG. 3. Details of the adapter 60 which has seven input pins and four output pins to be electrically connected between the plug 32 of output cable 30 and the electrical input plug of trailer 55 will be disclosed while referring to FIG. 5.

FIG. 4 of the drawings illustrates the DC test circuits which include the light selection toggle switches and the circuit breaker toggle switches that are accessible at the face of the chassis 1 (of FIG. 1) of the tester for testing the lighting systems of the commercial trailer 50 of FIG. 2 and the utility trailer 55 of FIG. 3. As was previously described, the power cord 5 and plug 7 are connected between the power supply 40 and an available 120-volt AC wall receptacle. Provided that the power switch 9 is depressed, the power supply 40 provides a 12-volt DC output voltage for powering selected ones of the lights of the trailer under test by way of seven conductors which are surrounded by the output cable 30 that is connected to the standard male input receptacle of the trailer 50 by means of the female plug 32.

The particular lights of the trailer to be powered and illuminated by the DC voltage supplied by power supply 40 are dependent upon the corresponding toggle switches which are actuated (i.e., rotated) in order to complete a selected one of the DC test circuits housed within the chassis 1. For example, the flasher circuit breaker toggle switch 20 is rotated to the closed circuit position and the turn signal indicator lights selection toggle switch 14 which is connected in series therewith is moved from the neutral switch position to one of the left or right switch positions to provide power to and test the turn signal indicator lights of the trailer via (white and yellow or green) conductors of the output cable 30. The flasher circuit breaker toggle switch 20 is moved to the closed circuit position and the hazard lights selection toggle switch 10 which is connected in series therewith is moved from the neutral switch position to one of the left or right switch positions to provide power to and test the hazard lights of the trailer via (white and yellow or green) conductors of the output cable 30. At the same time that the turn signal indicator lights or the hazard lights of the trailer are being powered and tested, the flasher 42 is energized to cause the light emitting diodes 25 and 26 to flash. If the left turn signal indicator light is functioning, the light emitting diode 25 will flash. If the right turn signal indicator light is functioning, the light emitting diode 26 will flash.

In the event it is desirable to test the functionality of the brake lights of the trailer, the brake lights circuit breaker toggle switch 22 is rotated to the closed circuit position, and the brake lights selection toggle switch 16 which is connected in electrical series therewith is moved to the closed switch position. Provided that the power switch 9 is depressed, DC power from the power supply 40 will be provided to the brake lights via a (red) conductor of the output cable 30.

In the event it is desirable to test the functionality of the running or courtesy lights of the trailer, the running/courtesy lights circuit breaker switch 24 is rotated to the closed circuit position, and the running/courtesy lights selection toggle switch 18 which is connected in electrical series therewith is rotated from the neutral switch position to one of the two switch positions corresponding to the running lights or the courtesy lights. Provided that the power switch 9 is depressed, DC power from the power supply 40 will be provided to the selected one of the running lights or courtesy lights via respective (brown or black) conductors of the output cable 30.

In the event it is desirable to test the functionality of the auxiliary lights of the trailer, the auxiliary lights circuit breaker switch 28 is rotated to the closed circuit switch position, and the auxiliary lights selection toggle switch 26 which is connected in series therewith is moved to the closed switch position. Provided that the power switch 9 is depressed, DC power from the power supply 40 will be provided to the auxiliary lights via a (blue) conductor of the output cable 30. As shown in FIGS. 1 and 4, only a single DC test circuit is provided to test the functionality of the auxiliary lights of the trailer. However, additional auxiliary test circuits can be provided where the trailer has more than one set of auxiliary lights.

As was earlier disclosed, rather than having to actuate the circuit breaker toggle switches 20, 22, 24 and 28 one at a time, all of the circuit breaker toggle switches may be rotated to the closed circuit position at the same time at the commencement of the test of the lighting system. Each toggle switch 20, 22, 24, and 28 is preferably a 20 amp DC circuit breaker. If an overload occurs or a short is present in the electrical wiring associated with the flasher 42 or any of the lights of the trailer being selectively tested, the corresponding DC circuit breaker toggle switch 20, 22, 24 or 28 will trip to the open circuit position to indicate a fault, whereby the DC test circuit in which the toggle switch is located will be broken. The identity of any wiring of the lighting system in need of repair can easily be detected by examining the face of the chassis 1 at which all of the circuit breaker toggle switches are located and visually accessible. It may be appreciated that use of the circuit breaker toggle switches 20, 22, 24 and 28 eliminates the requirement for fuses that must be replaced when blown which is known to result in wasted time and increased cost. The circuit breaker toggle switches 20, 22, 24, and 28 of the present invention will only need to be reset to the closed circuit position but not replaced.

As also earlier disclosed, in the event the lighting system of a commercial trailer (designated 50 in FIG. 2) is to be tested, the cylindrical female plug 32 at the end of the seven-conductor output cable 30 is connected directly to a male plug of the trailer 50. In the event the lighting system of a utility trailer (designated 55 in FIG. 3) is otherwise to be tested, the cylindrical female plug 32 of the seven-conductor output cable 30 is connected to the input power receptacle of the trailer 55 by way of the aforementioned seven-pin to four-pin coupler 60, the details of which are now provided while referring to FIG. 5.

FIG. 5 of the drawings is a ladder diagram illustrating the wiring logic of the coupler 60 to be connected between the plug 32 of the output cable 30 extending from the chassis 1 and the input power receptacle of the utility trailer 55. The designated colors of the conductors shown in FIG. 5 correspond with the colors of the conductors that were previously described when referring to FIG. 4. In the case of coupler 60, the black and blue conductors carried by the output cable 30 and used to test the courtesy and auxiliary lights of the commercial trailer 50 of FIG. 2 terminate at dead ends in the coupler 60 and are not used to test the lighting system of the utility trailer 55 of FIG. 3.

The coupler 60 includes a pair of DC relay coils 70 and 72 that are energized to close a corresponding pair of normally-open relays 74 and 76. Each relay coil 70 and 72 has the usual pair of relay terminals 78, 79 and 80, 81, and each relay 74 and 76 has the usual pair of relay contacts 82, 83 and 84, 85. Provided that the appropriate test circuit switches 16 and 22 have been closed at the chassis 1 of the electrical lighting tester shown in FIG. 1, the red conductor connected to input pin 4 of the coupler 60 supplies a signal to simultaneously energize both relay coils 70 and 72 and thereby close both relays 74 and 76. Thus, both brake lights 86 and 88 of the trailer 55 to which the yellow and green conductors of coupler 60 are connected will be illuminated at the same time as if an operator had manually depressed the brake pedal of a tow vehicle attached to the trailer.

A 12-volt DC signal is supplied from the DC power supply (designated 40 in FIG. 4) via the input pin 1 of coupler 60 and the white conductor thereof so as to power the lights under test. The running lights 90 of the trailer 55 are connected to the input pin 6 of the coupler 60 via the brown conductor thereof. Accordingly, it can be appreciated that the seven conductors carried by the output cable 30 of FIG. 4 are reduced to five (i.e., the white, yellow, green, red and brown) conductors which are connected between five input pins (designated 1, 3, 4, 5 and 6) but only four output pins at the coupler 60 of FIG. 5.

1. An electrical tester for testing the functionality of the lights of a lighting system of a vehicle-pulled trailer, said tester comprising:
a DC power supply; and
a plurality of electrical switches located in respective ones of a plurality of DC test circuits that are electrically connected to the lights to be tested, a particular one of said plurality of electrical switches adapted to be selectively actuated from an open switch position at which the DC test circuit in which said one electrical switch is located is disconnected from said DC power supply to a closed switch position at which to connect the DC test circuit to said DC power supply to cause a corresponding one of the lights to which the DC test circuit is connected to be powered and illuminated for testing.

2. The electrical tester recited in claim 1, further comprising a portable chassis surrounding said DC power supply and said DC test circuits in which said plurality of electrical switches are located, said chassis having a handle by which said chassis is carried to the site of the vehicle-pulled trailer to be tested.

3. The electrical tester recited in claim 1, wherein said DC power supply is a 120-volt AC/12-volt DC power supply.

4. The electrical tester recited in claim 1, further comprising a flasher circuit and at least one indicator light adapted to flash, each of said flasher circuit and said one indicator light interconnected with each other and with at least a first of said plurality of electrical switches, said flasher circuit causing said one indicator light to flash provided that the first of said plurality of electrical switches is selectively actuated to the closed switch position and the corresponding one of the lights to be tested is a functioning flashing light.

5. The electrical tester recited in claim 4, wherein the first of said plurality of electrical switches interconnected with said flasher and the flashing light has three switch positions, said first electrical switch being in the open switch position corresponding to a first of the three switch position when the flashing light of the trailer is not under test, and said first electrical switch being actuated to the closed switch position corresponding to a second of the three switch positions when the flashing light being tested is one of a right side light or a left side light of the trailer.

6. The electrical tester recited in claim 1, further comprising a circuit breaker connected in electrical series with each one of said plurality of electrical switches located in respective ones of said plurality of DC test circuits.

7. The electrical tester recited in claim 6, wherein said circuit breaker connected in electrical series with each one of said plurality of electrical switches includes a toggle switch having an open circuit position at which to cause the DC test circuit in which said series connected toggle switch is connected to be opened and a closed circuit position at which to close said DC test circuit.

8. The electrical tester recited in claim 1, wherein each of said plurality of electrical switches located in said respective DC test circuits includes a toggle switch having two switch positions, a first of said two-switch positions corresponding to the open switch position at which to disconnect the DC test circuit in which said toggle switch is located from said DC power supply, and the second of said two-switch positions corresponding to the closed switch position at which to connect the DC test circuit to said DC power supply.

9. The electrical tester recited in claim 1, wherein at least one of said plurality of electrical switches located in one of said plurality of DC test circuits is a toggle switch having three switch positions, a first of said three-switch positions corresponding to the open switch position at which to disconnect the DC circuit in which said toggle switch is located from said DC power supply, the second of said three-switch positions corresponding to the closed switch position at which to connect the one DC test circuit to a particular light of the lights of the trailer to be tested, and the third of said three-switch positions corresponding to the closed switch position at which to connect the one DC test circuit to a different light of the lights of the trailer to be tested.

10. The electrical tester recited in claim 1, wherein each of said plurality of DC test circuits is connected between said DC power supply and the lights of the trailer to be tested by means of an electrical output plug adapted to be detachably connected to a complementary electrical input plug located at the trailer in order to provide DC power from said DC power supply to the different ones of the lights of the trailer undergoing testing.

11. The electrical tester recited in claim 10, wherein there are a total of seven DC test circuits to be connected to the electrical input plug located at the trailer by means of said electrical output plug, said electrical tester further comprising a coupler connected to said electrical output plug and adapted to be mated to the electrical input plug at the trailer, said coupler having seven input pins to which respective ones of said seven DC test circuits are connected and four output pins to be mated to the electrical input plug to provide DC power from said DC power supply to the lights of the trailer undergoing testing.

12. An electrical tester for testing the functionality of the lighting system of a vehicle including lights to be tested, said tester comprising:
a portable chassis;
a DC power supply housed within said portable chassis;
a plurality of manually-actuated electrical switches located in respective DC test circuits and housed within said portable chassis, said DC test circuits connected between said DC power supply and the lights of the lighting system undergoing testing, said plurality of electrical switches adapted to be selectively actuated from an open switch position at which to disconnect the DC test circuits in which said electrical switches are connected from said DC power supply to a closed switch position at which to connect the DC test circuits to said DC power supply to cause the lights being tested to be powered and illuminated; and
a plurality of manually-actuated circuit breakers housed within said chassis and electrically connected in said DC test circuits in electrical series with respective ones of said plurality of electrical switches, said plurality of circuit breakers adapted to be selectively actuated from an open circuit position at which the DC test circuits in which said circuit breakers are connected are opened to a closed circuit position at which the DC test circuits are closed.

13. The electrical tester recited in claim 12, wherein said plurality of manually-actuated electrical switches and said plurality of manually-actuated circuit breakers are selectively actuated at the exterior of said portable chassis.

14. The electrical tester recited in claim 13, wherein at least some of said plurality of manually-actuated electrical switches and at least some of said plurality of manually-actuated circuit breakers each includes a toggle switch located at the exterior of said portable chassis.

15. The electrical tester recited in claim 12, wherein said DC power supply is a 120-volt AC/12-volt DC power supply.

16. The electrical tester recited in claim 12, further comprising a coupler electrically connected to at least some of said DC test circuits, said coupler including a relay coil and a relay having an open circuit condition, one of said at least some DC test circuits carrying a signal to energize said relay coil and thereby cause said relay to have a closed circuit condition, whereby to connect said DC power supply to a particular one of the lights to be tested when one of said plurality of electrical switches located in said one DC test circuit is actuated to the closed switch position and one of said plurality of circuit breakers connected in electrical series with said one electrical switch in said one DC test circuit is actuated to the closed circuit position.
